(19) United States
(12) Patent Application Publication
(10) Pub. No.: US 2013/0299838 A1
(43) Pub. Date: Nov. 14, 2013

(54) THIN-FILM TRANSISTOR ARRAY SUBSTRATE AND MANUFACTURING METHOD FOR THE SAME

(71) Applicants: Hua Huang, Shenzhen (CN); Pei Jia, Shenzhen (CN)

(72) Inventors: Hua Huang, Shenzhen (CN); Pei Jia, Shenzhen (CN)

(73) Assignee: SHENZHEN CHINA STAR OPTOELECTRONICS TECHNOLOGY CO., LTD., Shenzhen (CN)

(21) Appl. No.: 13/574,564

(22) PCT Filed: May 9, 2012
(86) PCT No.: PCT/CN12/75241

§ 371 Date: Jul. 20, 2012

(30) Foreign Application Priority Data
May 8, 2012 (CN) 201210140146.7

(51) Int. Cl. H01L 33/60; H01L 33/08

(52) U.S. Cl. 257/72; 438/29; 438/158; 257/E33.06

(57) ABSTRACT

A thin-film transistor (TFT) array substrate and manufacturing method thereof are disclosed herein. A first metal layer is deposited on a substrate, and a first mask is utilized for patterning the first metal layer to form a gate. A gate insulative layer and a semiconductive layer are deposited on the substrate, and a second mask is utilized to pattern the semiconductive layer except which above the gate is retained. A transparent conductive layer and a second metal layer are disposed on the substrate, and a multi-stage mask adjustment is used for patterning the transparent conductive layer and the second metal layer to form a source, a drain and a common electrode. A reflective layer is formed with the second metal layer on the common electrode.

### TECHNICAL FIELD OF THE INVENTION

The present invention relates to a liquid crystal manufacturing technology, and more particularly to, a thin-film transistor array substrate and a manufacturing method thereof.

### BACKGROUND OF THE INVENTION

With liquid crystal displays (LCDs) being increasingly popularized, performances of LCDs are highly demanded. In an exemplar of a transflective LCD, the transflective LCD still effects with a high-definition display in an outdoor environment when directly exposed to the sun and thereby is increasingly applied to the LCD field.

In a process of a TFT array substrate of the transflective LCD, a photo-lithography is performed by using a plurality of masks, especially in which a reflective layer is formed by an additional process after forming transparent pixel electrodes. However, increasing masks will also increase the costs needed for the TFT process, and in addition, the processing time and production complexity will be increased.

Therefore, the conventional technology with the need of an additional mask process to form a reflective layer invokes the TFT array substrate process of the transflective LCDs more complicated and more difficult, as well as higher costs. Also, this increases LCDs production difficulties.

### SUMMARY OF THE INVENTION

An objective of the present invention is to provide a manufacturing method of a thin-film transistor (TFT) array substrate so as to solve the technical problem of the prior art which invokes the TFT array substrate process of the transflective LCDs more complicated, more difficult and costly, as well as increasing LCDs production difficulties, due to the need of an additional mask process to form a reflective layer.

To solve the above-mentioned problem, the present invention provides a manufacturing method of a thin-film transistor (TFT) array substrate, and the method comprises steps as follows:
providing a substrate;
depositing a first metal layer on the substrate, and patterning the first metal layer by a first mask to form a gate;
depositing a gate insulative layer and a semiconductive layer sequentially on the substrate, patterning the semiconductive layer by a second mask to be partially above the gate;
depositing a transparent conductive layer and a second metal layer sequentially on the substrate, wherein the second metal layer is composed of a second molybdenum metal layer, a second aluminum metal layer, and a third molybdenum metal layer by sequentially forming, and by a multi-stage mask adjustment, the transparent conductive layer and the second metal layer are patterned, a source and a drain are formed with a part of both the patterned transparent conductive layer and the patterned second metal layer on the patterned semiconductive layer, a common electrode is formed with another part of the patterned transparent conductive layer on the gate insulative layer, and a reflective layer is formed with another part of the patterned second metal layer on the common electrode;
depositing a planarization layer on the common electrode, the reflective layer, the source and the drain both for a thin-film transistor, and the patterned semiconductive layer, wherein the planarization layer is formed with transparent insulative materials.

In the TFT array substrate manufacturing method of the present invention, the reflective layer is connected with the drain.

In the manufacturing method of the TFT array substrate of the present invention, the reflective layer and the drain are deposited apart from each other.

In the manufacturing method of the TFT array substrate of the present invention, the multi-stage mask adjustment includes a gray-scale tone mask, a stacking layer mask, or a half-tone mask.

In the manufacturing method of the TFT array substrate of the present invention, the first metal layer is composed of a first aluminum metal layer and a first molybdenum metal layer in sequential forming.

In the manufacturing method of the TFT array substrate of the present invention, the step of patterning the first metal layer by the first mask to form the gate comprises utilizing a mixture of nitric acid, phosphoric acid and acetic acid to wet-etch the first metal layer.

In the manufacturing method of the TFT array substrate of the present invention, the step of patterning the semiconductive layer by the second mask to be partially above the gate comprises utilizing a reactive ion etching method.

In the manufacturing method of the TFT array substrate of the present invention, the steps of respectively forming the reflective layer, and the source and the drain formed with a part of both the patterned transparent conductive layer and the patterned second metal layer on the patterned semiconductive layer by the multi-stage mask adjustment comprise utilizing a mixture of nitric acid, phosphoric acid and acetic acid to wet-etch the second metal layer, and utilizing a reactive ion etching method to dry-etch the transparent conductive layer;
the step of forming the common electrode with another part of the patterned transparent conductive layer on the gate insulative layer by the multi-stage mask adjustment comprises utilizing a reactive ion etching method to dry-etch the transparent conductive layer.

Another objective of the present invention is to provide a manufacturing method of a thin-film transistor (TFT) array substrate for solving the technical problem of the prior art such that an additional mask processing is required to form a reflective layer, thereby the TFTs process of the transflective LCDs is more complicated, as well as more processing difficulty and higher costs. LCDs production difficulties are increased.

In order to solve the above-mentioned problem, the present invention provides a manufacturing method of a thin-film transistor (TFT) array substrate, and the method comprises steps as follows:
providing a substrate;
depositing a first metal layer on the substrate, and patterning the first metal layer by a first mask to form a gate;
depositing a gate insulative layer and a semiconductive layer sequentially on the substrate, patterning the semiconductive layer by a second mask to be partially above the gate;
depositing a transparent conductive layer and a second metal layer sequentially on the substrate, and by a multi-stage mask adjustment, patterning the transparent conductive layer and the second metal layer, forming a source and a drain with a part of both the patterned transparent conductive layer and the patterned second metal layer on the patterned semiconductive layer, forming a common electrode with the patterned transparent conductive layer on the gate insulative layer, and forming a reflective layer with the patterned second metal layer on the common electrode.

In the manufacturing method of the TFT array substrate of the present invention, the reflective layer is connected with the drain.

In the manufacturing method of the TFT array substrate of the present invention, the reflective layer and the drain are deposited apart from each other.

In the manufacturing method of the TFT array substrate of the present invention, the method further comprises the following steps after forming the source, the drain, the common electrode, and the reflective layer:
depositing a planarization layer on the common electrode, the reflective layer, the source and the drain both for a thin-film transistor, and the semiconductive layer, wherein the planarization layer is formed with transparent insulative materials.

In the manufacturing method of the TFT array substrate of the present invention, the multi-stage mask adjustment includes a gray-scale tone mask, a stacking layer mask, or a half-tone mask.

In the manufacturing method of the TFT array substrate of the present invention, the first metal layer is composed of a first aluminum metal layer and a first molybdenum metal layer in sequential forming, the second metal layer is composed of a second molybdenum metal layer, a second aluminum metal layer and a third molybdenum metal layer in sequential forming.

In the manufacturing method of the TFT array substrate of the present invention, the step of patterning the first metal layer by the first mask comprises utilizing a mixture of nitric acid, phosphoric acid and acetic acid to wet-etch the first metal layer.

In the manufacturing method of the TFT array substrate of the present invention, the step of patterning the semiconductive layer by the second mask to be partially above the gate comprises utilizing a reactive ion etching method.

In the manufacturing method of the TFT array substrate of the present invention, the steps of respectively forming the reflective layer, the source and the drain formed with a part of both the patterned transparent conductive layer and the patterned second metal layer on the patterned semiconductive layer by the multi-stage mask adjustment comprise utilizing a mixture of nitric acid, phosphoric acid and acetic acid to wet-etch the second metal layer, and utilizing a reactive ion etching method to dry-etch the transparent conductive layer;
wherein the step of forming the common electrode with another part of the patterned transparent conductive layer on the gate insulative layer by the multi-stage mask adjustment comprises utilizing a reactive ion etching method to dry-etch the transparent conductive layer.

Another objective of the present invention is to provide a manufacturing method of a thin-film transistor (TFT) array substrate so as to solve the technical problem of the prior art such that an additional mask processing is required to form a reflective layer, thereby the TFTs process of the transflective LCDs is more complicated, as well as more processing difficulty and higher costs. LCDs production difficulties are increased.

In order to solve the above-mentioned problem, the present invention provides a thin-film transistor (TFT) array substrate which comprises:
a substrate;
a plurality of TFTs, disposed on the substrate, wherein each of the TFT comprises a gate, a gate insulative layer, a semiconductive layer, a source and a drain sequentially formed on the substrate, and the source and the drain both are formed with a transparent conductive layer and a metal layer;
a common electrode formed on the gate insulative layer;
a reflective layer formed with a second metal layer above the common electrode.

In the TFT array substrate of the present invention, the reflective layer is connected with the drain.

In the TFT array substrate of the present invention, the reflective layer and the drain are deposited apart from each other.

The present invention has advantages over the prior art in the thin-film transistor array substrate and manufacturing method as followings: forming the gate by the first mask after depositing the first metal layer on the substrate, proceeding with the second mask after depositing the gate insulative layer and a semiconductive layer, utilizing the multi-stage mask adjustment to form the source, the drain, the common electrode and the reflective layer after depositing the transparent conductive layer and the second metal layer, and thereby forming the TFT array substrate of the transflective LCDs. The present invention has simplified the manufacturing process, reduced the costs and difficulties of the process, and thereby increased LCD productions.

For better understanding of the aforementioned content of the present invention, the preferred embodiments are described in detail in conjunction with the appending figure as follows.

### BRIEF DESCRIPTION OF THE DRAWINGS

FIG. 1 illustrates a cross-sectional diagram of a display panel and a back-light module according to a preferred embodiment of the present invention;

FIG. 2A-2C illustrate cross-sectional diagrams of a thin-film transistor array substrate of the display panel according to the preferred embodiment of the present invention; and

FIG. 2D illustrates a cross-sectional diagram of a thin-film transistor array substrate of the display panel according to another embodiment of the present invention.

### DETAILED DESCRIPTION OF THE INVENTION

The respective embodiments will be described with reference to the appending drawings as follows, and they are specific embodiments for exemplifying that the present invention is able to be put into practice. The direction terms mentioned in present invention, for instance, “upper”, “lower”, “front”, “back”, “left”, “right”, “inner”, “outer”, “side”, so the direction terms only presents the direction of the appending drawings. Therefore, the direction terms is utilized for describing and understanding the invention, but not limiting the invention.

Elements having similar structures are labeled in the same numeral references to the figures.

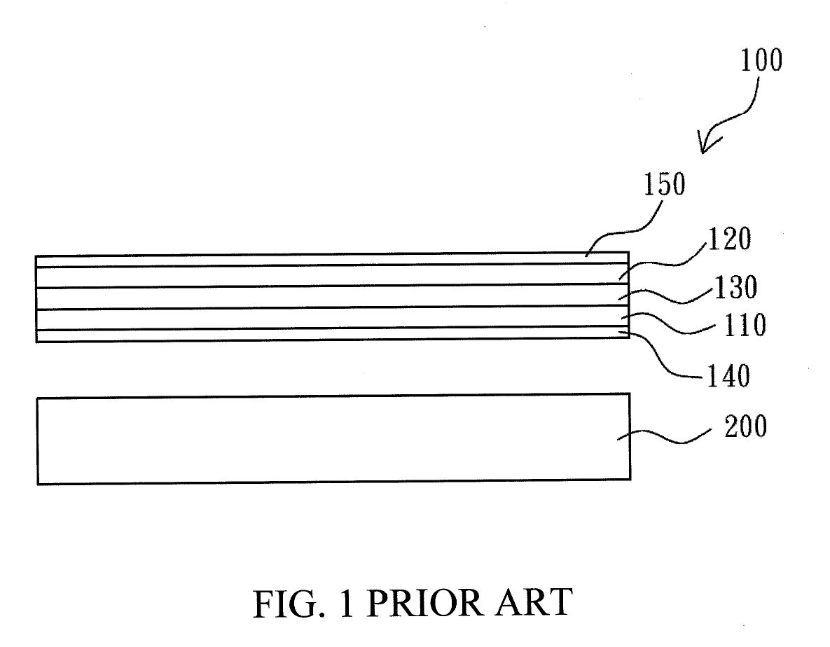

Referring to illustration shown in FIG. 1, FIG. 1 illustrates a cross-sectional diagram of a display panel and a back-light module according to a preferred embodiment of the present invention.

In this embodiment, the manufacturing method of a thin-film transistor (TFT) array substrate is applied in a process of manufacturing a display panel 100 (e.g. a liquid crystal display panel) in which a protective layer of the respective transistors is manufactured. When the display panel 100 according to this embodiment is applied for manufacturing a liquid crystal display device, the display panel 100 is disposed on a back-light module 200 so as to form the liquid crystal display device. The display panel 100 comprises a first substrate 110, a second substrate 120, a liquid crystal layer 130, a first polarizing plate 140, and a second polarizing plate 150. The substrate material of the first substrate 110 and the second substrate 120 may be glass substrates or flexible plastic substrates. In this embodiment, the first substrate 110 may be implemented with a TFT array substrate, and the second substrate 120 may be implemented with a color filter (CF) substrate. It notes that the TFT array substrate and the color filter may be disposed on the same substrate in some another embodiments.

As shown in FIG. 1, the liquid crystal layer 130 is formed between the first substrate 110 and the second substrate 120. The first polarizing plate 140 is disposed on one side of the first substrate 110 and corresponds to the liquid crystal layer 130 (i.e. the light incident side of the first substrate 110), the second polarizing plate 150 is disposed on one side of the second substrate 120 and corresponds to the liquid crystal layer 130 (i.e. the light emitting side of the second substrate 120).

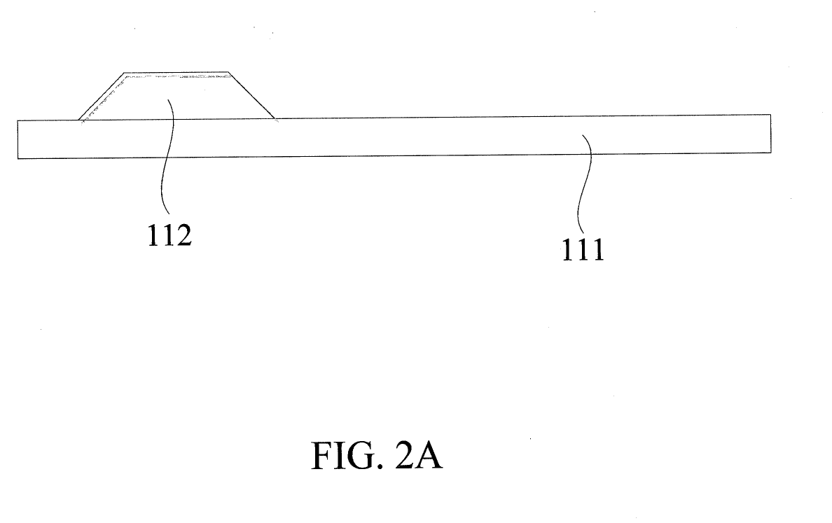

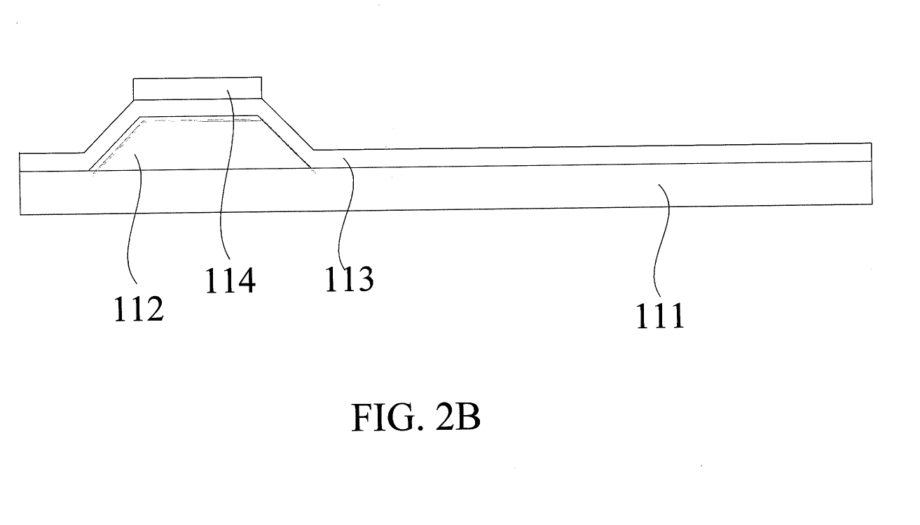

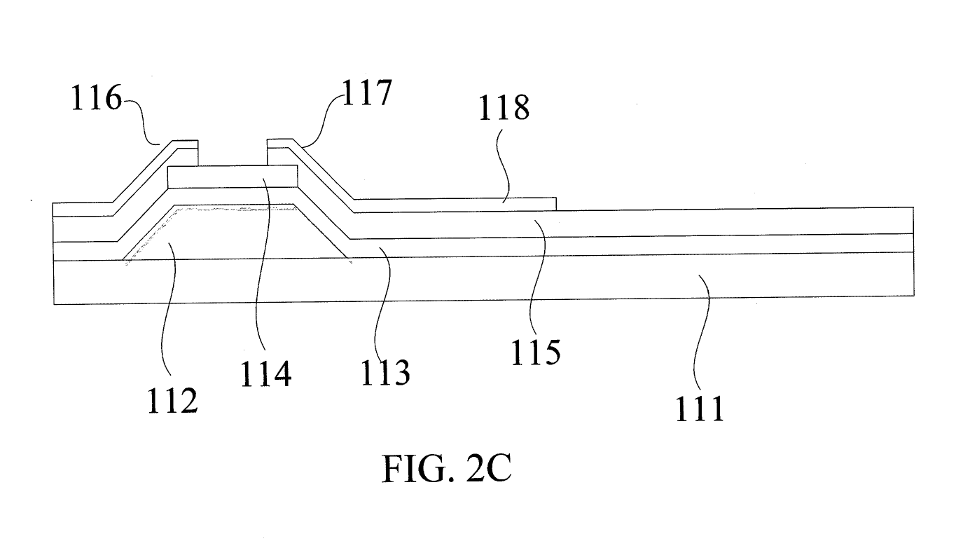

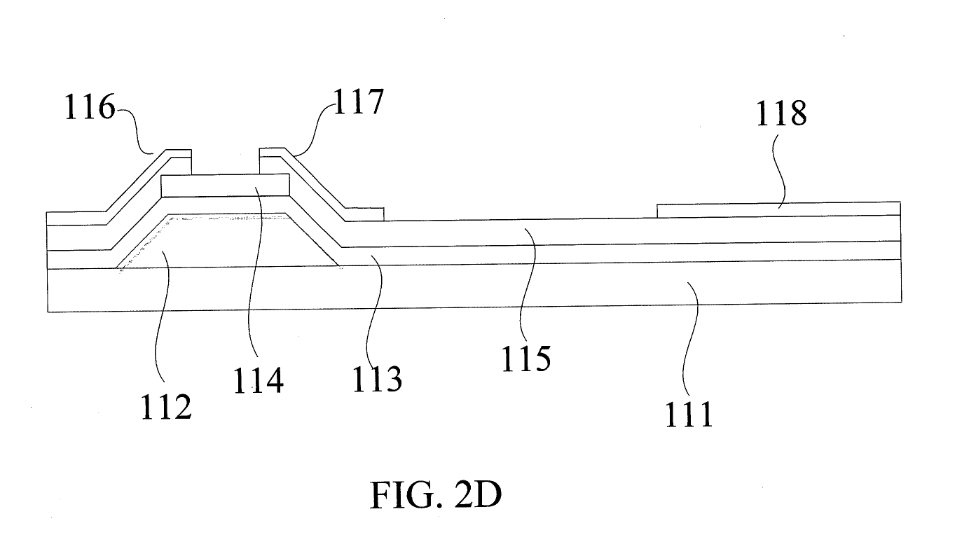

Referring to FIGS. 2A-2C, some cross-sectional diagrams of a TFT array substrate of the display panel are illustrated according to the preferred embodiment of the present invention.

As shown in FIG. 2A, a substrate 111 is provided on which a first metal layer is deposited by sequential forming. The first metal layer is proceeded with etching by a first mask, and a gate 112 is formed on the first metal layer, as well as the structure shown in FIG. 2A.

In this embodiment, the first metal layer is preferably composed of a first aluminum metal layer and a first molybdenum metal layer, besides other materials that may also be utilized, such as silver (Ag), copper (Cu), chromium (Cr), tungsten (W), tantalum (Ta), titanium (Ti), metal nitrides, or a combination thereof, and the first metal layer may be a multi-layer structure consisting of heat-resistant metal thin films and low-resistance thin films.

In a practical process, forming the first metal layer on the substrate 111 adopts a sputtering method, preferably. Then, the first metal layer is patterned by a photo-lithography method and the etching method with the first mask to form the gate 112 thereon, wherein the step of patterning the first metal layer by the first mask to form the gate 112 comprises preferably utilizing a mixture of nitric acid, phosphoric acid and acetic acid to wet-etch the first metal layer.

As shown in FIG. 2B, a gate insulative layer 113 and a semiconductive layer 114 are sequentially deposited on the substrate 111, and a second mask is utilized to pattern the semiconductive layer 114, except that the semiconductive layer 114 located above the gate 112 is retained, as forming the structure in FIG. 2B.

The present invention preferably utilizes a chemical vapor deposition such as a plasma enhanced chemical vapor deposition (PECVD) for depositing the gate insulative layer 113 and the semiconductive layer 114. Understandably, any other methods utilized for depositing the gate insulative layer 113 and the semiconductive layer 114 are not listed herein.

The materials of the gate insulative layer 113 may be silicon-nitride (SiNx) or silicon-oxide (SiOx), and the semiconductive layer 114 may be made of poly-silicon. In this embodiment, an amorphous-silicon (a-Si) layer is deposited firstly, and then a rapid thermal annealing (RTA) method is utilized on the amorphous-silicon (a-Si) layer so that the amorphous-silicon (a-Si) layer is recrystallized to a poly-silicon layer.

Referring to FIG. 2C, a transparent conductive layer and a second metal layer sequentially deposited on the substrate 111 by the sputtering method are introduced, wherein the thickness of the transparent conductive layer is preferably equal to or less than 100 μm. By a multi-stage mask adjustment, the transparent conductive layer and the second metal layer are patterned, a source 116 and a drain 117 are formed with a part of both the patterned transparent conductive layer and the patterned second metal layer on the patterned semiconductive layer, a common electrode 115 is formed with another part of the patterned transparent conductive layer on the gate insulative layer 113, and a reflective layer 118 is formed with another part of the patterned second metal layer on the common electrode 115.

The transparent conductive layer is preferably formed by transparent conductive metals, such as indium tin oxide (ITO), tin oxide (TO), indium zinc oxide (IZO), and indium tin zinc oxide (ITZO).

The second metal layer is preferably composed of a second molybdenum metal layer, a second aluminum metal layer, and a third molybdenum metal layer, respectively, other materials may be utilized, such as silver (Ag), copper (Cu), chromium (Cr), tungsten (W), tantalum (Ta), titanium (Ti), metal nitrides, or a combination thereof, also the second metal layer may be a multi-layer structure consisting of heat-resistant metal thin films and low-resistance thin films.

In the practical process, the multi-stage mask adjustment adopts a multi-stage photomask adjustment which may be implemented with a gray-scale tone mask (GTM), a stacking layer mask (SLM), or a half-tone mask (HTM). The multi-stage photomask adjustment may cover exposure areas, partial exposure areas, and unexposed areas so that the source 116 and the drain 117 are formed with a part of both the patterned transparent conductive layer and the patterned second metal layer on the patterned semiconductive layer, a common electrode 115 is formed with another part of the patterned transparent conductive layer on the gate insulative layer 113, and a reflective layer 118 is formed with another part of the patterned second metal layer on the common electrode 115, wherein the reflective layer 118 is connected with the drain 117.

In the steps of respectively forming the reflective layer, the source 116 and the drain 117 formed with a part of both the patterned transparent conductive layer and the patterned second metal layer on the patterned semiconductive layer 114 by the multi-stage mask adjustment, a mixture of nitric acid, phosphoric acid and acetic acid is utilized to wet-etch the second metal layer, and a reactive ion etching (RIE) method is utilized to dry-etch the transparent conductive layer. In the step of forming the common electrode 115 with another part of the patterned transparent conductive layer on the gate insulative layer 114 by the multi-stage mask adjustment, a reactive ion etching method is utilized to dry-etch the transparent conductive layer.

In the preferred embodiment, after the structure shown in FIG. 2C is formed, a planarization layer (not shown) may be deposited on the common electrode 115, the reflective layer 118, the semiconductive layer 114, and the source 116 and the drain 117 both for the TFT so as to effect on planarization and component protection. The planarization layer is preferably formed by transparent insulative materials, besides other suitable materials that are not listed herein.

Referring to FIG. 2D, in another embodiment of the present invention, the reflective layer 118 and the drain 117 are deposited apart from each other as disconnected therebetween when the source 116 and the drain 117 are formed on the patterned semiconductive layer, the common electrode 115 is formed with another part of the patterned transparent conductive layer on the gate insulative layer 113, and the reflective layer 118 is formed with another part of the patterned second metal layer on the common electrode 115, by utilizing the multi-stage mask adjustment to pattern the transparent conductive layer and the second metal layer. It notes that after the structure in FIG. 2D is formed, a planarization layer may still be deposited on the common electrode 115, the reflective layer 118, the semiconductive layer 114, and the source 116 and the drain 117 both for the TFT.

The present invention further provides a TFT array substrate, which comprises a substrate and a plurality of TFTs disposed on the substrate.

The TFT comprises a gate 112, a gate insulative layer 113, a semiconductive layer 114, a source 116, and a drain 117. The gate 112, the gate insulative layer 113 and the semiconductive layer 114 are sequentially formed on the substrate 111. The gate 112 is formed with the first metal layer deposited on the substrate 111. The source 116 and the drain 117 are located on the semiconductive layer 114. The source 116 and the drain 117 both are formed with a transparent conductive layer and a metal layer which are sequentially deposited on the semiconductive layer 114.

The TFT further comprises a common electrode 115 and a reflective layer 118. The common electrode 115 is formed with the transparent conductive layer deposited on the gate insulative layer 113, and the reflective layer 118 is formed with the second metal layer located above the common electrode 115.

The thin-film transistor array substrate and a manufacturing method according to the present invention utilizes only three masks to accomplish the thin-film transistor array substrate of the transflective LCDs without use of an additional mask process to produce the reflective layer so that the number of the masks needed during the manufacturing process may be reduced, as well as the costs and the time of the process are reduced.

To sum up, the present invention has been disclosed as the preferred embodiments above, however, the above preferred embodiments are not described for limiting the present invention, various modifications, alterations and improvements can be made by persons skilled in this art without departing from the spirits and principles of the present invention, and therefore the protection scope of claims of the present invention is based on the range defined by the claims.

1. A manufacturing method of a thin-film transistor (TFT) array substrate, comprising steps of:
providing a substrate;
depositing a first metal layer on the substrate, and patterning the first metal layer by a first mask to form a gate;
depositing a gate insulative layer and a semiconductive layer sequentially on the substrate, patterning the semiconductive layer by a second mask to be partially above the gate;
depositing a transparent conductive layer and a second metal layer sequentially on the substrate, wherein the second metal layer is composed of a second molybdenum metal layer, a second aluminum metal layer, and a third molybdenum metal layer by sequentially forming, and by a multi-stage mask adjustment, the transparent conductive layer and the second metal layer are patterned, a source and a drain are formed with a part of both the patterned transparent conductive layer and the patterned second metal layer on the patterned semiconductive layer, a common electrode is formed with another part of the patterned transparent conductive layer on the gate insulative layer, and a reflective layer is formed with another part of the patterned second metal layer on the common electrode; and
depositing a planarization layer on the common electrode, the reflective layer, the source and the drain both for a thin-film transistor, and the patterned semiconductive layer, wherein the planarization layer is formed with transparent insulative materials.

2. The manufacturing method of claim 1, wherein the reflective layer is connected with the drain.

3. The manufacturing method of claim 1, wherein the reflective layer and the drain are deposited apart from each other.

4. The manufacturing method of claim 1, wherein the multi-stage mask adjustment includes a gray-scale tone mask, a stacking layer mask, or a half-tone mask.

5. The manufacturing method of claim 1, wherein the first metal layer is composed of a first aluminum metal layer and a first molybdenum metal layer in sequential forming.

6. The manufacturing method of claim 1, wherein the step of patterning the first metal layer by the first mask to form the gate comprises utilizing a mixture of nitric acid, phosphoric acid and acetic acid to wet-etch the first metal layer.

7. The manufacturing method of claim 1, wherein the step of patterning the semiconductive layer by the second mask to be partially above the gate comprises utilizing a reactive ion etching method.

8. The manufacturing method of claim 1, wherein the steps of respectively forming the reflective layer, the source and the drain formed with a part of both the patterned transparent conductive layer and the patterned second metal layer on the patterned semiconductive layer by the multi-stage mask adjustment comprise utilizing a mixture of nitric acid, phosphoric acid and acetic acid to wet-etch the second metal layer, and utilizing a reactive ion etching method to dry-etch the transparent conductive layer; and
the step of forming the common electrode with another part of the patterned transparent conductive layer on the gate insulative layer by the multi-stage mask adjustment comprises utilizing a reactive ion etching method to dry-etch the transparent conductive layer.

9. A manufacturing method of a thin-film transistor (TFT) array substrate, comprising steps of:
providing a substrate;
depositing a first metal layer on the substrate, and patterning the first metal layer by a first mask to form a gate;
depositing a gate insulative layer and a semiconductive layer sequentially on the substrate, patterning the semiconductive layer by a second mask to be partially above the gate; and
depositing a transparent conductive layer and a second metal layer sequentially on the substrate, and by a multi-stage mask adjustment, patterning the transparent conductive layer and the second metal layer, forming a source and a drain with a part of both the patterned transparent conductive layer and the patterned second metal layer on the patterned semiconductive layer, forming a common electrode with the patterned transparent conductive layer on the gate insulative layer, and forming a reflective layer with the patterned second metal layer on the common electrode.

10. The manufacturing method of claim 9, wherein the reflective layer is connected with the drain.

11. The manufacturing method of claim 9, wherein the reflective layer and the drain are deposited apart from each other.

12. The manufacturing method of claim 9, after the steps of forming the source, the drain, the common electrode and the reflective layer, further comprising steps of:
depositing a planarization layer on the common electrode, the reflective layer, the source and the drain both for a thin-film transistor, and the semiconductive layer, wherein the planarization layer is formed with transparent insulative materials.

13. The manufacturing method of claim 9, wherein the multi-stage mask adjustment includes a gray-scale tone mask, a stacking layer mask, or a half-tone mask.

14. The manufacturing method of claim 9, wherein the first metal layer is composed of a first aluminum metal layer and a first molybdenum metal layer in sequential forming, the second metal layer is composed of a second molybdenum metal layer, a second aluminum metal layer and a third molybdenum metal layer in sequential forming.

15. The manufacturing method of claim 9, wherein the step of patterning the first metal layer by the first mask comprises utilizing a mixture of nitric acid, phosphoric acid and acetic acid to wet-etch the first metal layer.

16. The manufacturing method of claim 9, wherein the step of patterning the semiconductive layer by the second mask to be partially above the gate comprises utilizing a reactive ion etching method.

17. The manufacturing method of claim 9, wherein the steps of respectively forming the reflective layer, the source and the drain formed with a part of both the patterned transparent conductive layer and the patterned second metal layer on the patterned semiconductive layer by the multi-stage mask adjustment comprise utilizing a mixture of nitric acid, phosphoric acid and acetic acid to wet-etch the second metal layer, and utilizing a reactive ion etching method to dry-etch the transparent conductive layer; and
the step of forming the common electrode with another part of the patterned transparent conductive layer on the gate insulative layer by the multi-stage mask adjustment comprises utilizing a reactive ion etching method to dry-etch the transparent conductive layer.

18. A thin-film transistor (TFT) array substrate, comprising:
a substrate;
a plurality of TFTs, disposed on the substrate, wherein each of the TFT comprises a gate, a gate insulative layer, a semiconductive layer, a source and a drain sequentially formed on the substrate, and the source and the drain both are formed with a transparent conductive layer and a metal layer;
a common electrode formed on the gate insulative layer; and
a reflective layer formed with a second metal layer above the common electrode.
